(19) United States
(12) Patent Application Publication
(10) Pub. No.: US 2026/0194757 A1
(43) Pub. Date: Jul. 9, 2026

(54) SMART GLASSES DEVICE AND SMART TERMINAL

(71) Applicants: Fu Tai Hua Industry (Shenzhen) Co., Ltd., Shenzhen (CN); HON HAI PRECISION INDUSTRY CO., LTD., New Taipei (TW)

(72) Inventor: Yu-Zhong Feng, Shenzhen (CN)

(21) Appl. No.: 19/215,579

(22) Filed: May 22, 2025

(30) Foreign Application Priority Data
Jan. 8, 2025 (CN) 202510034822.X

(51) Int. Cl. G02B 27/01; H05K 7/20

(52) U.S. Cl. CPC G02B 27/0176; H05K 7/202; G02B 2027/0152; G02B 2027/0154; G02B 2027/0161; G02B 2027/0169; G02B 2027/0178

(57) ABSTRACT

A smart glasses device includes a glasses assembly, a heat dissipating assembly, and a connecting assembly. The glasses assembly includes a first housing defining a first inlet and a first outlet. The heat dissipating assembly includes a second housing defining a second outlet and a second inlet. The connecting assembly is connected to the glasses assembly and the heat dissipating assembly. The connecting assembly includes an air inlet tube and an air outlet tube. The air inlet tube communicates with the second outlet and the first inlet. The air outlet tube communicates with the first outlet and the second inlet. The air inlet tube can transfer a first airflow to the glasses assembly. The air outlet tube can output a second airflow from the glasses assembly. A temperature of the first airflow is lower than a temperature of the second airflow. The present disclosure further provides a smart terminal.

### FIELD

The subject matter herein generally relates to terminals, and more particularly, to a smart glasses device and a smart terminal having the smart glasses device.

### BACKGROUND

Smart glasses may not be able to balance among the requirements such as light weight, heat dissipation, and waterproofing performance. For example, when the heat dissipation components are omitted from the smart glasses to reduce weight, the smart glasses may have poor heat dissipation performance, affecting user experience. When the smart glasses are equipped with a cooling fan to dissipate the heat, the weight of the smart glasses is increased, resulting in large burden on the forehead and nose bridge of the user during a long time use. Additionally, an opening is required on a housing of the smart glasses to facilitate the airflow generation by the fan, but the opening deteriorates the waterproof performance of the smart glasses. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view of an embodiment of a smart glasses device according to an embodiment of the present disclosure.

FIG. 2 is a diagrammatic view illustrating a glasses assembly of the smart glasses device in FIG. 1.

FIG. 3 is a diagrammatic view showing an inner structure of the glasses assembly in FIG. 2.

FIG. 4 is a diagrammatic view illustrating a heat dissipating assembly of the smart glasses device in FIG. 1.

FIG. 5 is an inner diagrammatic view of the heat dissipating assembly in FIG. 4.

FIG. 6 is a cross-sectional view of a connecting assembly along a view line A-A of the smart glasses device in FIG. 1.

FIG. 7 is a diagrammatic view of the connecting assembly of the glasses assembly in FIG. 1.

FIG. 8 is a block diagram of an embodiment of a smart terminal according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

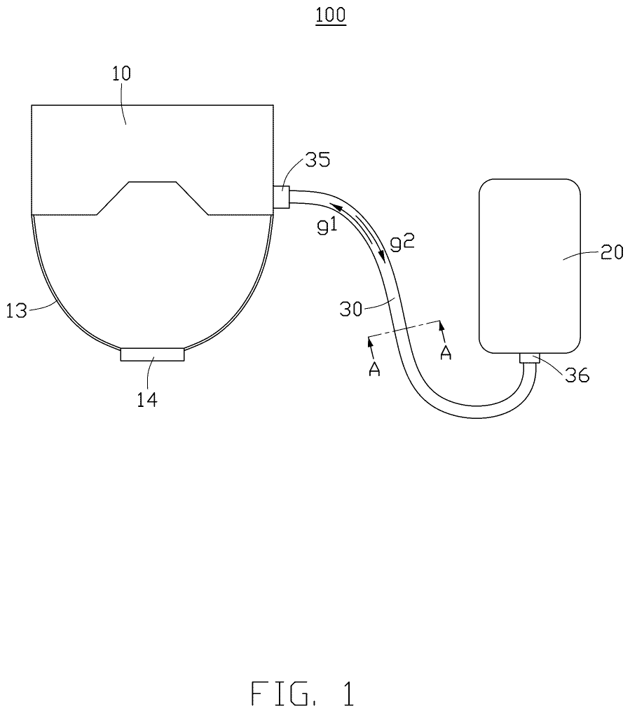

Referring to FIG. 1, a smart glasses device 100 is provided according to an embodiment of the present disclosure. The smart glasses device 100 may include a glasses assembly 10, a heat dissipating assembly 20, and a connecting assembly 30. The connecting assembly 30 is connected to the glasses assembly 10 and the heat dissipating assembly 20. The glasses assembly 10 may generate heat during operation. The heat dissipating assembly 20 can transfer a first airflow g1 to the glasses assembly 10 through the connecting assembly 30. The glasses assembly 10 can output a second airflow g2 to the heat dissipating assembly 20 through the connecting assembly 30. The second airflow g2 can carry the heat generated by the glasses assembly 10, and a temperature of the first airflow g1 is lower than a temperature of the second airflow g2, thereby achieving cooling of the glasses assembly 10.

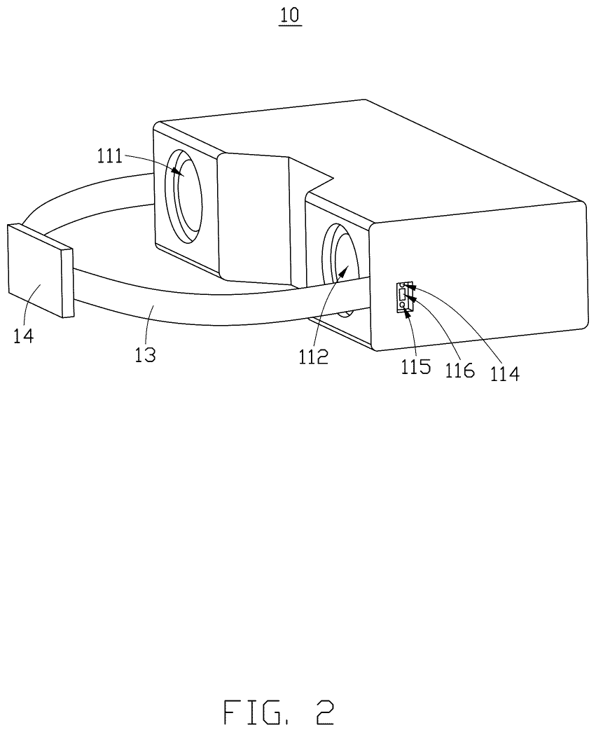

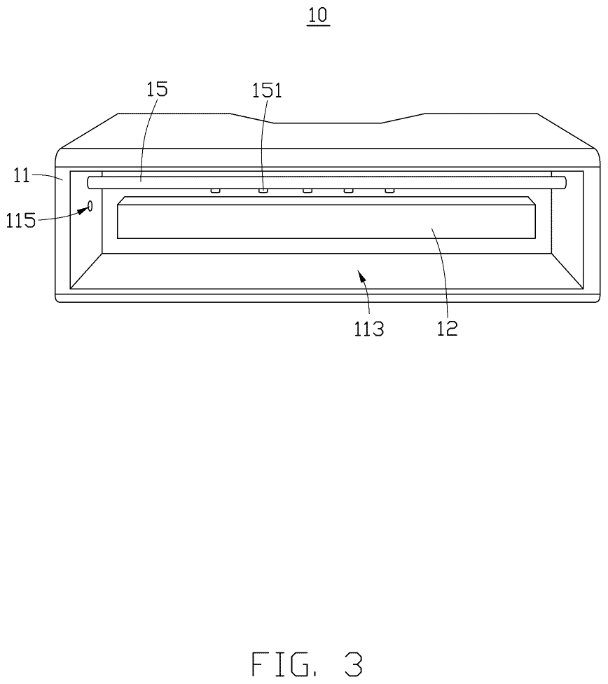

Referring to FIGS. 2 and 3, the glasses assembly 10 may include a first housing 11, a functional mechanism 12, a headband 13, and an adjusting member 14. The functional mechanism 12 is accommodated in the first housing 11. The headband 13 is connected to the first housing 11. The headband 13 is used to secure on the head of a user. The adjusting member 14 is disposed on the headband 13 to adjust a length of the headband 13 to accommodate different sizes of the head. The length adjustment of the headband 13 may include manual adjustment and electric adjustment.

The first housing 11 may include a left eye viewing hole 111 and a right eye viewing hole 112, which are corresponding to the left eye and right eye of the user, respectively. The user can view the display content of the glasses assembly 10 through the left eye viewing hole 111 and the right eye viewing hole 112.

The first housing 11 may further include a receiving cavity 113. The functional mechanism 12 is accommodated in the receiving cavity 113. The functional mechanism 12 can realize the display function of the glasses assembly 10. The functional mechanism 12 may include circuit modules, display modules, lens groups, flat cables, and sensors. At least some components of the functional mechanism 12 can generate heat during operation.

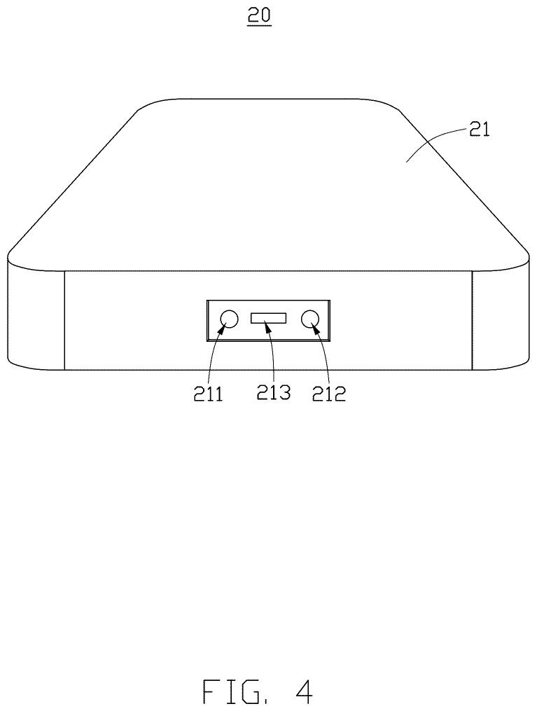

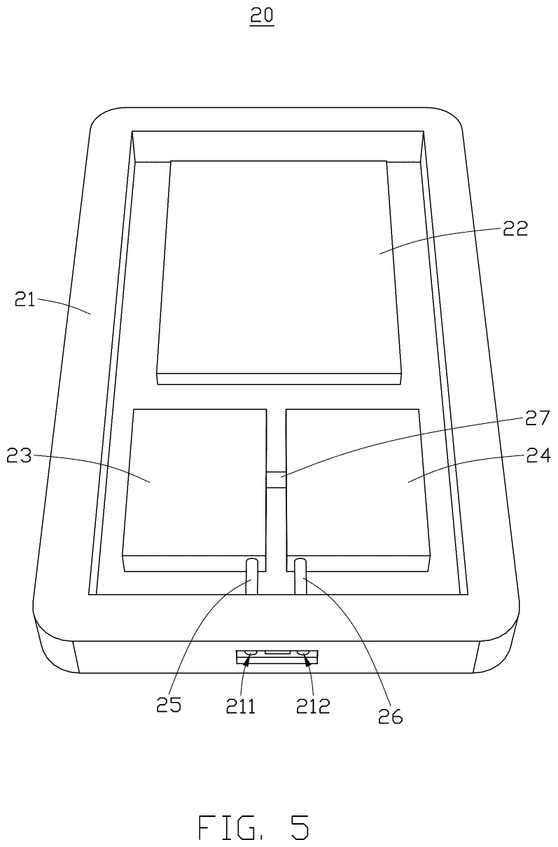

Referring to FIGS. 4 and 5, the heat dissipating assembly 20 may include a second housing 21, a battery 22, an air supply module 23, and a gas cooling module 24. The battery 22, the air supply module 23, and the gas cooling module 24 are all accommodated in the second housing 21. The battery 22 can provide power for the air supply module 23 and the gas cooling module 24, and may further provide power for the glasses assembly 10. The air supply module 23 can generate the first airflow g1 and transfer the first airflow g1 to the glasses assembly 10. The gas cooling module 24 can cool down the second airflow g2 entering the heat dissipating assembly 20. When the battery 22 provides power for the glasses assembly 10, the battery 22 in the glasses assembly 10 can be omitted, thereby reducing a weight of the glasses assembly 10 and improving user experience.

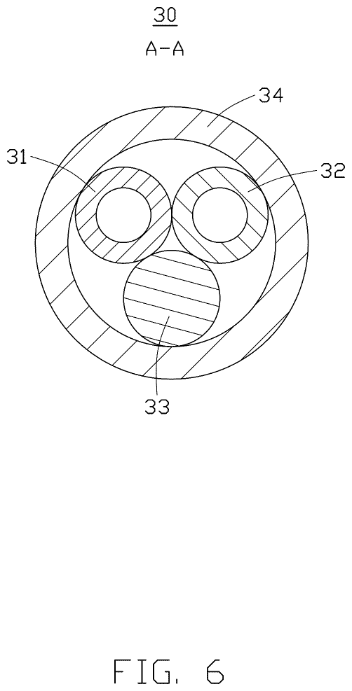

Referring to FIG. 2, a first inlet 114 and a first outlet 115 are defined on the first housing 11. The first outlet 115 communicates with the receiving cavity 113. Referring to FIG. 4, a second outlet 211 and a second inlet 212 are defined on the second housing 21. Referring to FIG. 6, the connecting assembly 30 includes an air inlet tube 31 and an air outlet tube 32. The air inlet tube 31 communicates with the second outlet 211 and the first inlet 114. The air outlet tube 32 communicates with the first outlet 115 and the second inlet 212. When the glasses assembly 10 needs to be cooled down, the air supply module 23 generates the first airflow g1, which flows through the second outlet 211, the air inlet tube 31, the first inlet 114 and enters the glasses assembly 10 in sequence. Then, the first airflow g1 is exchanged with the air in the glasses assembly 10. The exchanged air carries heat to form the second airflow g2, which flows through the first outlet 115, the air outlet tube 32, the second inlet 212 and enters the heat dissipating assembly 20 in sequence. The heat dissipating assembly 20 cools the second airflow g2 entering the heat dissipating assembly 20 to facilitate air recycling. It can be understood that the temperature of the first airflow g1 is lower than the temperature of the second airflow g2.

Referring to FIG. 3, the glasses assembly 10 may further include a tube 15 accommodated in the receiving cavity 113. One end of the tube 15 communicates with the first inlet 114. At least one air outlet 151 is defined on the tube 15. The air outlet 151 faces the functional mechanism 12 that require heat dissipation. The first airflow g1, which enters the glasses assembly 10 through the first inlet 114, further flows through the tube 15 and is output through the air outlet 151 toward the components requiring heat dissipation, thereby achieving cooling of high-temperature areas. Additionally, the air outlet 151 reduces an area of air outlet, which increases airflow velocity and further enhances the cooling efficiency.

Referring again to FIG. 5, the heat dissipating assembly 20 may further include a first tube 25, a second tube 26, and a third tube 27. The first tube 25 communicates with the air supply module 23 and the second outlet 211. The second tube 26 communicates with the second inlet 212 and the gas cooling module 24. The third tube 27 communicates with the gas cooling module 24 and the air supply module 23.

Referring to FIG. 6, the connecting assembly 30 may further include a sleeve 34 and a cable assembly 33. The cable assembly 33, air inlet tube 31, and air outlet tube 32 are accommodated in the sleeve 34. The connecting assembly 30 is roughly in a linear shape, and its shape can be adjusted according to requirements.

A first data interface 116 is provided on the first housing 11 (referring to FIG. 2), and a second data interface 213 is provided on the second housing 21 (referring to FIG. 4). Two ends of the cable assembly 33 can connect to the first data interface 116 and the second data interface 213, respectively. The glasses assembly 10 and the heat dissipating assembly 20 are connected to each other through the cable assembly 10. The cable assembly 33 can achieve communicating and/or power connection between the glasses assembly 10 and the heat dissipating assembly 20.

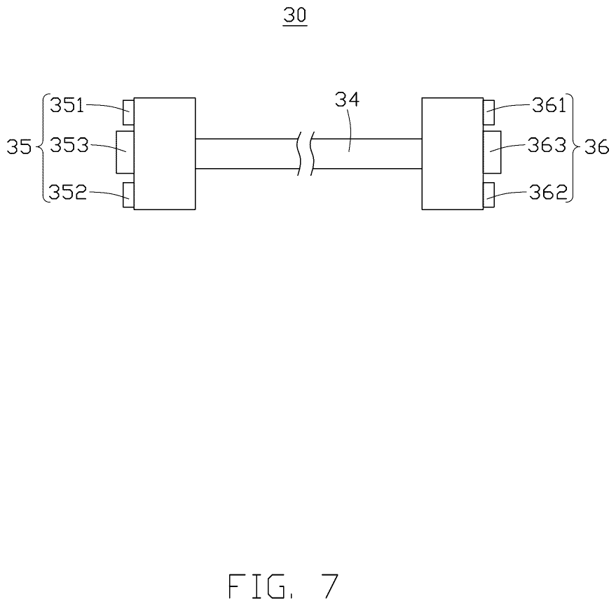

Referring to FIG. 7, the connecting assembly 30 may further include a first connector 35 and a second connector 36. The first connector 35 and the second connector 36 form two ends of the connecting assembly 30. The first connector 35 is connected to the glasses assembly 10, and the second connector 36 is connected to the heat dissipating assembly 20. The connecting assembly 30 is detachably connected to the glasses assembly 10 and the heat dissipating assembly 20 through the first connector 35 and the second connector 36.

The first connector 35 includes a first inserting hole 351, a second inserting hole 352, and a first data communicate hole 353. The first inserting hole 351 communicates the air inlet tube 31 with the first inlet 114. The second inserting hole 352 communicates the first outlet 115 with the air outlet tube 32. The first data communicate hole 353 is electronically connected to the cable assembly 33 and the first data interface 116. The second connector 36 includes a third inserting hole 361, a fourth inserting hole 362, and a second data communicate hole 363. The third inserting hole 361 communicates the air inlet tube 31 with the second outlet 211. The fourth inserting hole 362 communicates the second inlet 212 with the air outlet tube 32, and the second data communicate hole 363 is electronically connected to the cable assembly 33 and the second data interface 213.

According to the smart glasses device 100 provided in the above embodiments, the heat dissipating assembly 20 is connected to the glasses assembly 10 through the connecting assembly 30 and disposed outside of the glasses assembly 10. Thus, the smart glasses device 100 reduces a weight of the glasses assembly 10 while achieving the heat dissipation function, thereby improving comfort when the user wears the glasses assembly 10, thus enhancing the user experience. The first inlet 114 and first outlet 115 are defined on the first housing 11 of the glasses assembly 10, and the second inlet 212 and second outlet 211 are defined on the second housing 21 of the heat dissipating assembly 20. The air inlet tube 31 communicates with the second outlet 211 and the first inlet 114, and the air outlet tube 32 communicates with the first outlet 115 and the second inlet 212. Thus, fewer openings are defined on the first housing 11 and second housing 21. The first housing 11 and second housing 21 connected through the air inlet tube 31 and air outlet tube 32 form a sealed space where the air in the smart glasses device 100 forms an internal circulation, thereby providing excellent waterproof performance. Therefore, the smart glasses device 100 may balance among lightweight, excellent heat dissipation, and waterproof performance.

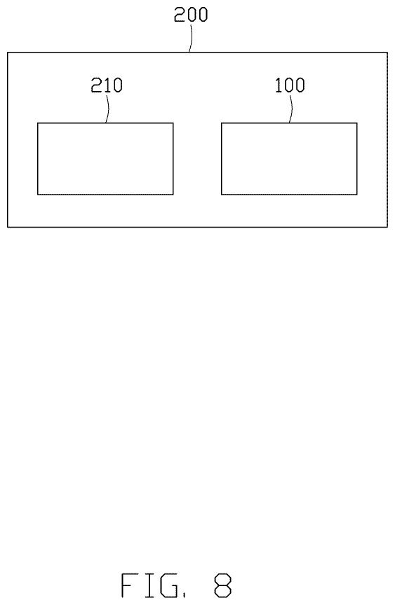

Referring to FIG. 8, a smart terminal 200 is further provided according to an embodiment of the present disclosure. The smart terminal 200 may include the smart glasses device 100 and a glasses case 210. The glasses case 210 can accommodate the smart glasses device 100. When the smart glasses device 100 needs to be used, the smart glasses device 100 can be taken out from the glasses case 210. When the smart glasses device 100 is not in use, the smart glasses device 100 can be accommodated in the glasses case 210 for easy carrying and protection.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

1. A smart glasses device comprising:
a glasses assembly comprising a first housing, the first housing defining a first inlet and a first outlet;
a heat dissipating assembly comprising a second housing, the second housing defining a second outlet and a second inlet; and
a connecting assembly connected to the glasses assembly and the heat dissipating assembly, the connecting assembly comprising an air inlet tube and an air outlet tube, the air inlet tube communicating with the second outlet and the first inlet, and the air outlet tube communicating with the first outlet and the second inlet,
wherein the air inlet tube is configured to transfer a first airflow to the glasses assembly, the air outlet tube is configured to output a second airflow from the glasses assembly, and a temperature of the first airflow is lower than a temperature of the second airflow;
wherein the connecting assembly further comprises a first connector, a second connector, a sleeve and a cable assembly, the cable assembly, the air inlet tube, and the air outlet tube are accommodated in the sleeve; and the glasses assembly and the heat dissipating assembly are connected to each other through the cable assembly; and
wherein the first connector comprises a first data communicate hole, the first housing comprises a first data interface, and the first data communicate hole is configured to electronically connect to the cable assembly and the first data interface; the second connector comprises a second data communicate hole, the second housing comprises a second data interface, and the second data communicate hole is configured to electronically connect to the cable assembly and the second data interface.

2. The smart glasses device of claim 1, wherein the heat dissipating assembly further comprises an air supply module and a gas cooling module, each of the air supply module and the gas cooling module is accommodated in the second housing, the air supply module is configured to generate the first airflow and transfer the first airflow to the glasses assembly, and the gas cooling module is configured to cool down the second airflow entering the heat dissipating assembly.

3. The smart glasses device of claim 2, wherein the heat dissipating assembly further comprises a first tube, a second tube and a third tube, the first tube communicates with the air supply module and the second outlet, the second tube communicates with the second inlet and the gas cooling module, and the third tube communicates with the gas cooling module and the air supply module.

4. The smart glasses device of claim 2, wherein the heat dissipating assembly further comprises a battery accommodated in the second housing, and the battery is electrically connected to the air supply module, the gas cooling module, and the glasses assembly.

5. The smart glasses device of claim 1, wherein the first connector further defines a first inserting hole and a second inserting hole, the first inserting hole is configured to communicate with the air inlet tube and the first inlet, and the second inserting hole is configured to communicate with the first outlet and the air outlet tube; the second connector further defines a third inserting hole and a fourth inserting hole, the third inserting hole is configured to communicate with the air inlet tube and the second outlet, and the fourth inserting hole is configured to communicate with the second inlet and the air outlet tube.

6-7. (canceled)

8. The smart glasses device of claim 1, wherein the glasses assembly comprises a functional mechanism and a tube, each of the functional mechanism and the tube is accommodated in the first housing, the tube communicates with the first inlet; the tube defines at least one air outlet facing the functional mechanism.

9. The smart glasses device of claim 1, wherein the glasses assembly comprises a headband and an adjusting member, the headband is connected to the first housing, and the adjusting member is on the headband.

10. A smart terminal comprising:
a smart glasses device comprising:
a glasses assembly comprising a first housing, the first housing defining a first inlet and a first outlet;
a heat dissipating assembly comprising a second housing, the second housing defining a second outlet and a second inlet; and
a connecting assembly connected to the glasses assembly and the heat dissipating assembly, the connecting assembly comprising an air inlet tube and an air outlet tube, the air inlet tube communicating with the second outlet and the first inlet, and the air outlet tube communicating with the first outlet and the second inlet; wherein the air inlet tube is configured to transfer a first airflow to the glasses assembly, the air outlet tube is configured to output a second airflow from the glasses assembly, and a temperature of the first airflow is lower than a temperature of the second airflow;
wherein the connecting assembly further comprises a first connector, a second connector, a sleeve and a cable assembly, the cable assembly, the air inlet tube, and the air outlet tube are accommodated in the sleeve; and the glasses assembly and the heat dissipating assembly are connected to each other through the cable assembly; and
wherein the first connector comprises a first data communicate hole, the first housing comprises a first data interface, and the first data communicate hole is configured to electronically connect to the cable assembly and the first data interface; the second connector comprises a second data communicate hole, the second housing comprises a second data interface, and the second data communicate hole is configured to electronically connect to the cable assembly and the second data interface; and
a glasses case configured to accommodate the smart glasses device.

11. The smart terminal of claim 10, wherein the heat dissipating assembly further comprises an air supply module and a gas cooling module, each of the air supply module and the gas cooling module is accommodated in the second housing, the air supply module is configured to generate the first airflow and transfer the first airflow to the glasses assembly, and the gas cooling module is configured to cool down the second airflow entering the heat dissipating assembly.

12. The smart terminal of claim 11, wherein the heat dissipating assembly further comprises a first tube, a second tube and a third tube, the first tube communicates with the air supply module and the second outlet, the second tube communicates with the second inlet and the gas cooling module, and the third tube communicates with the gas cooling module and the air supply module.

13. The smart terminal of claim 11, wherein the heat dissipating assembly further comprises a battery accommodated in the second housing, and the battery is electrically connected to the air supply module, the gas cooling module, and the glasses assembly.

14. The smart terminal of claim 10, wherein the first connector further defines a first inserting hole and a second inserting hole, the first inserting hole is configured to communicate with the air inlet tube and the first inlet, and the second inserting hole is configured to communicate with the first outlet and the air outlet tube; the second connector further defines a third inserting hole and a fourth inserting hole, the third inserting hole is configured to communicate with the air inlet tube and the second outlet, and the fourth inserting hole is configured to communicate with the second inlet and the air outlet tube.

15-16. (canceled)

17. The smart terminal of claim 10, wherein the glasses assembly comprises a functional mechanism and a tube, each of the functional mechanism and the tube is accommodated in the first housing, the tube communicates with the first inlet; the tube defines at least one air outlet facing the functional mechanism.

18. The smart terminal of claim 10, wherein the glasses assembly comprises a headband and an adjusting member, the headband is connected to the first housing, and the adjusting member is on the headband.
